(19) United States
(12) Patent Application Publication
(10) Pub. No.: US 2005/0074679 A1
(43) Pub. Date: Apr. 7, 2005

(54) Method of manufacturing semiconductor device

(75) Inventor: Masahito Hiroshima, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC

(21) Appl. No.: 10/954,473

(22) Filed: Oct. 1, 2004

(30) Foreign Application Priority Data
Oct. 3, 2003 (JP) 346092/2003

(51) Int. Cl. G03F 9/00; G03F 7/00

(52) U.S. Cl. 430/5; 430/311; 430/396

(57) ABSTRACT

In a mask layout having aperture patterns successively arranged in a discrete manner, a pattern pitch P is set to a value prescribed by 0.69λ/NA≦P≦0.85λ/NA where λ is an exposure light wavelength and NA is the numerical aperture of a projection lens. This enables formation, with high controllability, of a device pattern having a chevron pattern that selectively has large aperture portions. A mask pattern is formed with only maximum aperture patterns (142) and a pitch (145) with respect to the aperture patterns (142) is designed as the foregoing prescribed value. When diffracted light through this mask pattern forms images on a resist, a resist pattern (148) having a continuous chevron shape is formed by processingly overlapping those images.

This application claims priority to prior application JP 2003-346092, the disclosure of which is incorporated herein by reference.

### BACKGROUND OF THE INVENTION

This invention relates to a semiconductor device manufacturing method that optimizes a mask layout pattern to achieve a high process performance in a lithography process being one of semiconductor device manufacturing processes.

The lithography process serves to transfer and reproduce on an underlayer film a layout pattern of an integrated circuit on an equivalent scale. For this, a photomask having a layout pattern equivalent to a desired device pattern is first fabricated. Then, short-wavelength partially-coherent light is irradiated onto this mask, and the light diffracted upon passing through the mask is condensed by a projection lens so as to be projected onto a wafer on a reduced scale. In this event, optimization of the process conditions is attempted so that an optical image of the device pattern formed on the wafer has a desired shape. Herein, the process conditions include an exposure time or an accumulated exposure amount, a focus offset value, and so forth.

FIGS. 1A, 1B, and 1C show pattern formation according to a conventional process technique. FIG. 1A shows a mask pattern 111, FIG. 1B shows an optical image simulation result 112, and FIG. 1C shows a resist shape image 113.

However, when the current process conditions still have room for the optimization, a resist pattern formed based on the transferred optical image is subjected to occurrence of deviations in shape and size at critical portions as compared with the desired device pattern. Therefore, portions to be corrected are extracted from the actually obtained resist pattern, and appropriate correction amounts are estimated from an experimental or simulation-based result and fed back to the mask layout. This routine is repeated until a resist pattern fully agrees with the desired device pattern within an error range allowable in terms of device operation.

Referring to FIG. 2, description will be given about conventional mask pattern correction methods. Cases that require correction can be roughly classified into four as follows. The first case is that, at an extremely critical portion of a desired device pattern, a resist size of that portion is thinner or thicker exceeding a dimensional error allowable in terms of device operation (120 in FIG. 2). The second case is that, at an end portion of a rectangular pattern elongate in one direction or at an open end portion of an infinitely long line pattern, a resist shape corresponding to that portion is shrunk exceeding a dimensional error allowable in terms of device operation (124 in FIG. 2). The third case is that, at a corner of a cranked layout pattern, a resist shape of that portion is subjected to rounding exceeding a dimensional error allowable in terms of device operation (126 in FIG. 2). The fourth case is that when a finest dense pattern and isolated patterns with sizes corresponding thereto and with various pitches are collectively transferred onto a resist to form images, the resolution performance differs per pattern pitch such that the resolution limit is lowered as the pattern pitch increases under the illumination condition using a modified lighting, and therefore, only the isolated patterns cannot obtain excellent resolution properties (122 in FIG. 2).

For the first case, processing is carried out to locally thicken or thin a portion 121, corresponding to the portion where the error in resist size has occurred, on a mask pattern to thereby match a transferred size on a resist with the desired size within the allowable error range. This operation is called bias processing with respect to the initial mask layout.

The second case relates to a phenomenon caused by the fact that the light intensity of the transferred optical image is extremely lowered at the line open end portion. By adding a hammer-like protrusion OPC pattern 125 called a hammerhead to the portion concerned, the lowered light intensity of that portion is supplemented to suppress the shrinkage of the resist.

For the third case, an apron rectangular pattern called a serif is added to an outer line side of the corner bent at right angle, i.e. an outer corner portion 128, while the same pattern is logically subtracted from an inner line side of the corner, i.e. an inner corner portion 127, to thereby enhance the shape of the corner to reduce the corner rounding amount.

For the fourth case, auxiliary patterns 123 each having a size equal to or less than the resolution limit and a shape similar to the pattern concerned are repeatedly arranged near the isolated patterns so that the isolated patterns, in effect, has periodicity and therefore diffracted light having passed through the subject mask pattern exhibits extremely high coherence, thereby achieving high resolution performance.

These conventional mask pattern correction methods are based on a concept that, on the basis of the initial layout completely equivalent to the desired device pattern, those portions that are unmatched with the resist pattern are removed by correction on the mask layout. Therefore, when a device pattern that requires the ability exceeding the resolution limit of an exposure tool is transferred and formed on a resist, it is not possible to achieve a sufficient transfer accuracy only by the mask layout correction according to the conventional OPC (optical proximity effect correction) technique.

The conventional pattern correction technique is based on a major premise that a desired device pattern is a simplified rectangular pattern. Therefore, layout data correction objects are roughly classified into the following two cases. The first case is a case of carrying out bias processing by parallel-shifting a side forming a rectangular pattern or a local segment thereof. The second case is a case of logically adding or subtracting a minute rectangular pattern at a corner for enhancing the rectangular shape thereof. In other words, it is considered that the conventional layout correction technique is achieved only in a simplified technique applied to an extremely simplified pattern. Therefore, when a complicated geometrical pattern having curved portions is transferred and formed on a resist, it is not expected to achieve a high transfer accuracy only by the conventional layout correction technique.

The foregoing conventional mask pattern correction methods have the following problems.

The first problem is that it is necessary in a manufacturing process of a semiconductor integrated circuit that a device pattern having a chevron shape that selectively has large aperture portions (a doughboy-shaped pattern having a continuous hole shape, wherein pattern sides form a mountain-shaped pattern or a fish-backbone-shaped pattern along a direction of wiring being a continuous portion) be transferred onto a resist to form an image thereof, but it is quite difficult for the conventional lithography technique to control a desired shape with high accuracy.

The reason is that, in the fine processing of deep half submicron generation, the resolution performance of exposure tools and resist materials now in use is not sufficiently high so that it is difficult to achieve a high processing accuracy.

The second problem is that the conventional OPC technique for supplementing the resolution performance of the current exposure tools and resist materials cannot be effectively applied or, although it takes much time and labor to calculate an appropriate OPC correction amount, the transfer accuracy is not sufficiently satisfactory.

The reason is that an OPC arranged at a bent portion is a two-dimensional minute rectangular pattern and thus parameters to be examined include three factors, i.e. an arranging position thereof and dimensions thereof in respective two-dimensional directions, so that combinations of the parameters become extensive to make it difficult to improve the efficiency in optimization operation. A further reason is that the current standardized OPC technique is effective only for a pattern having regular shapes and arrangements, but cannot achieve a sufficient correction effect for a chevron pattern requiring special shapes and positional relationship.

The third problem is that, in a technique of facilitating pattern formation by applying fine slits that are not resolved, there is the possibility of, as an adverse influence following the slit introduction, occurrence of pattern degradation due to non-intended pattern cutting or change in process condition.

The reason is that as the scale of a pattern becomes finer, the influence exerted upon a transferred pattern by the slit width increases, and therefore, in order to achieve the maximum effect from the slit introduction without causing the adverse influence due to the slit introduction, it is necessary to fully quantify a proper slit width.

Techniques similar to the contents of this invention are described in JP-A-H01-302256 (FIGS. 1 to 3) and JP-A-H10-142769 (FIGS. 5 and 6). JP-A-H01-302256 discloses a technical idea wherein, by providing a slit, which is not resolved, at a center portion of an elongate rectangular pattern, a desired elongate rectangular mask pattern shape can be transferred and formed with high accuracy. JP-A-H10-142769 discloses a technical idea wherein, in a mask layout where elongate rectangular patterns are densely arranged, an unresolvable slit is arranged at a center portion of each pattern, thereby suppressing distortion of an optical image caused when a focus offset value changes, so that shorts between the adjacent patterns can be avoided.

Both publications aim to transfer and form on a resist a pattern equivalent to the desired simple elongate rectangular pattern, and the unresolvable slit is inserted only for that purpose. Further, there is no teaching about the width of the unresolvable slit that can achieve the desired effect.

Therefore, this invention clearly differs from the foregoing publications in that unresolvable slits are used for transferring and forming a specific chevron pattern with high accuracy and high controllability on a resist. Further, this invention verifies an optical physical phenomenon of the half submicron generation by optical simulation and realizes quantification of the width of the unresolvable slit that can achieve the highest inventive effect in such a processing generation.

### SUMMARY OF THE INVENTION

It is an object of this invention to form a chevron pattern having continuity and periodically having large aperture portions on a resist with high controllability in the fine processing of the deep half submicron generation.

The other objects of this invention will become apparent as description proceeds.

In this invention, by setting the minimum separation width between aperture patterns to a prescribed value in a mask layout where the aperture patterns are successively arranged in a discrete manner and by selecting the optimum process conditions, it is possible to form, with high controllability, a chevron pattern selectively having large aperture portions (a doughboy-shaped pattern having a continuous hole shape, wherein pattern sides form a mountain-shaped pattern or a fish-backbone-shaped pattern along a direction of wiring being a continuous portion). The mask pattern is formed with only the maximum aperture patterns and a gap between the maximum aperture patterns is designed as a slit pattern. By exposing this mask and processingly overlapping optical images, a resist pattern having a continuous chevron shape is formed.

According to this invention, it is possible to form, with high controllability, aperture portions as large as possible on a layout and constricted portions each connecting between them to provide mutual continuity. Since the aperture portion has an extremely high light intensity, it is possible to obtain an excellent resist profile with higher rectangularity and a large aperture depth.

Further, according to this invention, owing to a light adding effect between the adjacent aperture portions, the light intensity increases to maximum at sweet spots of the aperture portions so that an optical image becomes quite sharp, thereby obtaining an excellent transferred shape.

Moreover, according to this invention, although a pattern is a discrete hole pattern on a mask, a transferred pattern has continuity to obtain a line optical property so that dependency of CD relative to a focus change can be reduced, thereby increasing the process tolerance as a lithography property.

### BRIEF DESCRIPTION OF THE DRAWINGS

FIG. 1A is a diagram showing a mask pattern for explaining pattern formation according to a conventional process technique;

FIG. 1B is a diagram showing an optical image simulation result for explaining the pattern formation according to the conventional process technique;

FIG. 1C is a diagram showing a resist shape image for explaining the pattern formation according to the conventional process technique;

FIG. 2 is a diagram for explaining conventional mask pattern correction methods;

FIGS. 3A, 3B, and 3C are diagrams showing mask patterns, optical image simulation results, and resist shape images according to conventional techniques and this invention;

FIG. 4 is a diagram showing optimization examined results about separation widths necessary for obtaining a desired chevron shape;

FIG. 5A is a diagram showing a mask layout for explaining an outline of this invention;

FIG. 5B is a resist image diagram for explaining the outline of this invention;

FIG. 6A is a diagram showing resist dimensional properties relative to a pattern pitch for explaining a prescribed pattern pitch for obtaining a chevron shape;

FIG. 6B is a diagram showing degrees of chevron relative to the pattern pitch for explaining the prescribed pattern pitch for obtaining the chevron shape;

FIG. 7A is a diagram showing a CD-focus property of a discrete hole, wherein there is shown behavior of a resist dimensional property upon occurrence of a focus change;

FIG. 7B is a diagram showing a CD-focus property of a resist pattern having a chevron shape, wherein there is shown behavior of a resist dimensional property upon occurrence of a focus change;

FIG. 8A is a diagram illustrating mask pattern images, for showing a correlation between a mask pattern shape and a light intensity distribution;

FIG. 8B is a diagram illustrating light intensity distributions, for showing the correlation between the mask pattern shape and the light intensity distribution;

FIG. 9 is a diagram showing an example of application to an ion-implantation resist mask process requiring a chevron shape;

FIG. 10 is a diagram showing dependency of an optical image dimension relative to a width of a node portion;

FIG. 11A is a diagram showing a pattern image based on a current layout rule for explaining a cell pattern image of an asymmetric implantation process;

FIG. 11B is a diagram showing a pattern image when the pattern image in FIG. 11A is shrunk to 90%, for explaining the cell pattern image of the asymmetric implantation process;

FIG. 12A is a diagram showing pattern extraction from an original layout for explaining in detail the operation procedure of this invention;

FIG. 12B is a diagram showing mask pattern size optimization for explaining in detail the operation procedure of this invention;

FIG. 12C is a diagram showing process condition optimization for explaining in detail the operation procedure of this invention;

FIG. 13 is a flowchart showing an operation procedure of this invention;

FIG. 14A is a diagram illustrating a first mask layout pattern, for showing a mask pattern and a resist shape image;

FIG. 14B is a diagram illustrating a second mask layout pattern, for showing the mask pattern and the resist shape image;

FIG. 14C is an image diagram of a resist profile for showing the mask pattern and the resist shape image;

FIG. 15A is a diagram illustrating a mask layout pattern for showing an outline of a resist pattern forming process having a chevron shape;

FIG. 15B is a resist pattern image diagram for showing the outline of the resist pattern forming process having the chevron shape;

FIG. 16A is a diagram showing formation of a line chevron pattern for explaining another embodiment of this invention; and

FIG. 16B is a diagram showing formation of an aperture pattern having a chevron shape by the use of a negative tone resist for explaining the another embodiment of this invention.

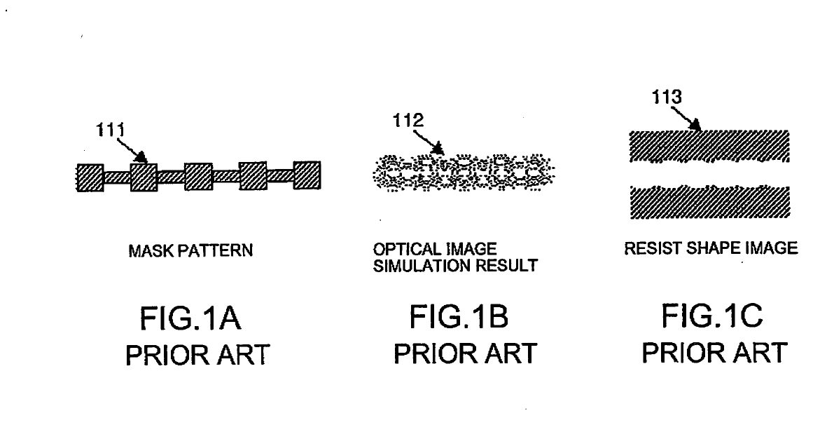

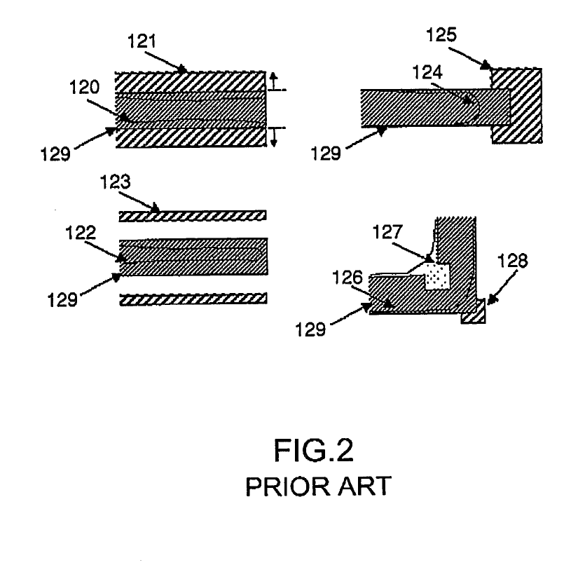

### DESCRIPTION OF THE PREFERRED EMBODIMENTS

This invention is premised on a layout in which adjacent patterns can be continuously connected together, and is a new semiconductor device manufacturing method capable of forming a resist pattern that is required to selectively provide those portions requiring a sufficient aperture area and a complete aperture property down to an underlay.

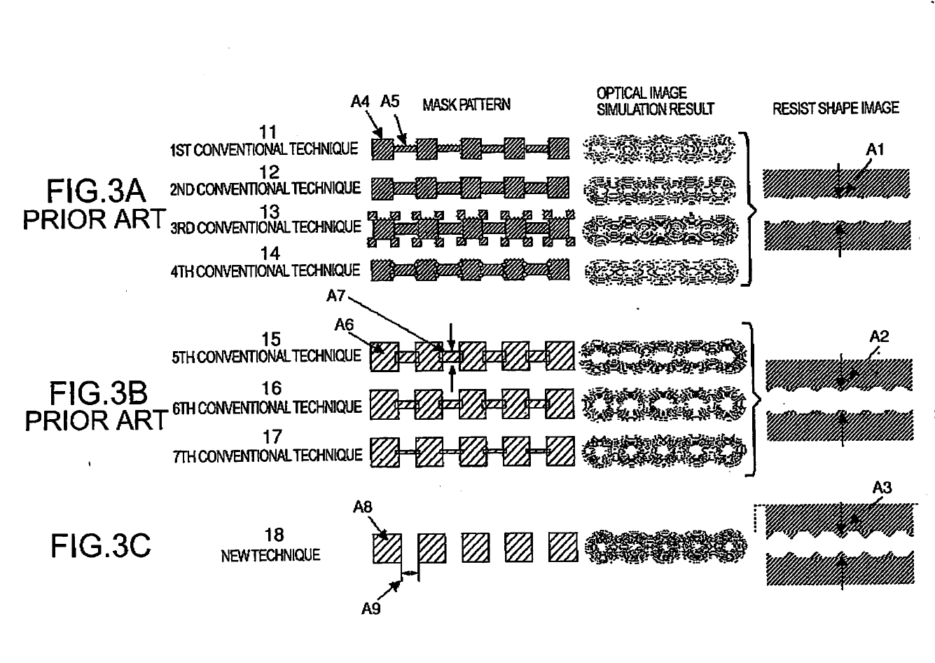

FIGS. 3A, 3B, and 3C show mask patterns, optical image simulation results, and resist shape images according to conventional techniques and this invention. FIG. 3A shows mask correction techniques and correction results by the use of conventional OPCs, FIG. 3B shows correction results in case of applying biases only to aperture portions, and FIG. 3C shows a correction result in case of using a new technique according to this invention. FIG. 3A shows the first to fourth conventional techniques 11 to 14, FIG. 3B shows the fifth to seventh conventional techniques 15 to 17, and FIG. 3C shows the new technique 18.

In FIGS. 3A, 3B, and 3C, A1, A2, and A3 in the resist shape images represent constrictions of resist aperture portions. In FIG. 3A, A4 and A5 in the mask pattern represent a mask pattern of a large-area portion and a mask pattern of a connection portion, respectively. In FIG. 3B, A6 and A7 in the mask pattern represent a mask pattern of a large-area portion and a mask pattern of a connection portion, respectively. In FIG. 3C, A8 and A9 in the mask pattern represent a mask pattern of a large-area portion and a slit pattern.

With respect to the mask pattern according to the new technique 18 shown in FIG. 3C wherein the large-aperture patterns A8 are successively arranged in a discrete manner, by designing the separation width A9 between the large-aperture patterns A8 as a prescribed value and optimizing the process conditions (accumulated exposure amount, exposure time, and focus offset value of an exposure tool), a resist pattern having a chevron shape A3 that selectively has large-aperture portions can be formed with high controllability. Herein, the chevron shape A3 is a doughboy-shaped pattern having a continuous hole shape, wherein pattern sides thereof form a mountain-shaped pattern or a fish-backbone-shaped pattern along a direction of wiring being a continuous portion.

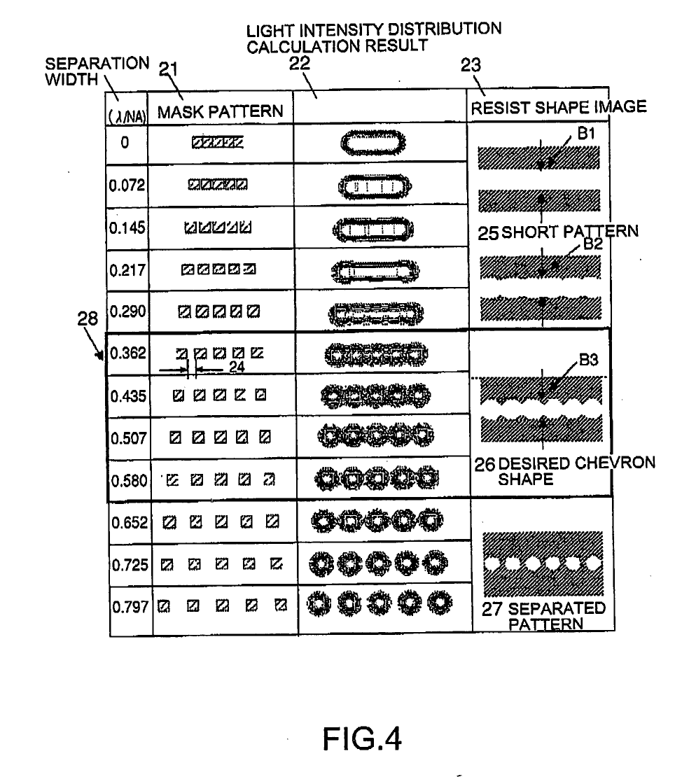

The prescription range of the separation width A9 shown in FIG. 3C is calculated from simulation results shown in FIG. 4.

In FIG. 4, numerals 21, 22, and 23 represent mask patterns, light intensity distribution simulation results, and resist shape images, respectively. The mask patterns are each composed of five square patterns arranged in a one-side chain fashion, wherein a separation width 24 between the square patterns is changed in the range of 0.0 to 0.797λ/NA. The width dimension is a value obtained by standardizing a linear scale with a wavelength λ of exposure light and the numerical aperture NA of a projection lens.

In FIG. 4, the light intensity distributions 22 are each obtained by contour-plotting intensities of the light projected onto a wafer or a resist on a two-dimensional map, wherein when the light forming an image has sharp waveforms and high intensities, the intervals between contours are quite narrowed (light contrast is high). Further, when the adjacent optical waveforms mutually interfere so as to have continuity, contours of them are connected together at the same light intensity portion. Therefore, selecting the optimum process conditions is nothing more than uniquely selecting the contour level of the light intensity that can achieve a desired resist shape. Therefore, in order to obtain the desired resist shape, it is necessary to select the separation width that achieves the highest optical contrast at a large-aperture portion among the light intensity distributions 22 in FIG. 4 and the resist shape having constricted portions that are most constricted among constricted portions B1, B2, and B3 of resist patterns in FIG. 4. In FIG. 4, a thick rectangular line 28 surrounds a condition region that satisfies the foregoing conditions.

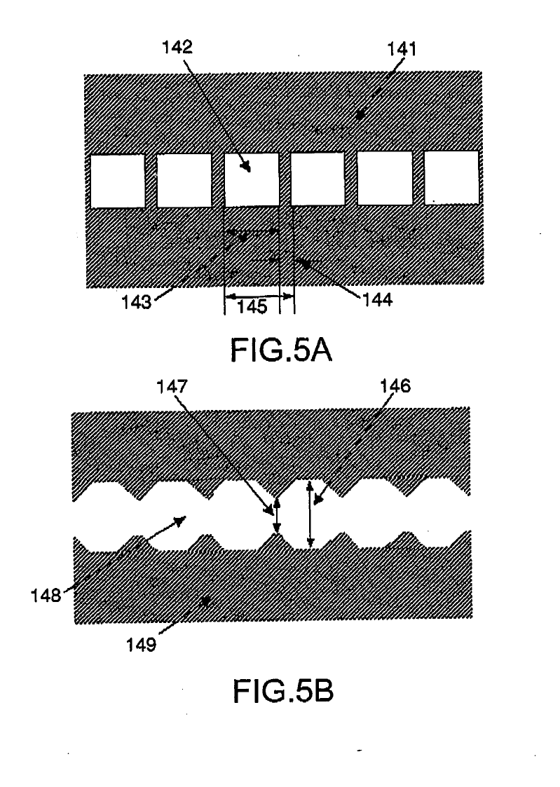

However, as shown in FIG. 5A, in order to control a chevron shape in a mask pattern having a shielding portion 141 and transmitting portions 142, it is necessary to add a pattern length 143 of a large-aperture portion to a separation width 144 between large-aperture patterns. Accordingly, a pitch 145 between the large-aperture patterns is adopted as an index for prescribing a process condition that is necessary and sufficient for achieving the chevron shape.

Herein, pattern pitches on a mask and dimensional properties of optical images were derived by optical simulation with respect to all process conditions that were actually applicable, to thereby calculate a region of mask pattern pitches that are necessary and sufficient for obtaining the desired chevron shape. Process conditions handled as parameters in the simulation were such that an exposure light wavelength λ was set to 0.248 μm (KrF excimer laser) and the numerical apertures NA of projection lenses mounted in a projection reduction exposure tool were set in the range from 0.6 of low resolution specification to 0.9 of practically maximum resolution specification, wherein target minimum aperture dimensions were set to values calculated by a theoretical formula (resolving power)=k1×λ/NA for the exposure light wavelength λ and the respective numerical apertures NA of the projection lenses. It is considered that the k1 factor represents process factors other than the exposure light wavelength λ and the numerical aperture NA of the projection lens that affect the resolution performance and mainly represents the resolution performance of a resist itself that is used. Herein, as illustrated in the following table 1, assumption is made about the resist process having an extremely high resolution performance (k1 factor=0.35) and the resist process having a low resolution performance (k1 factor=0.5).

TABLE 1

| | HIGH | LOW |
|---|---|---|
| | PERFORMANCE | PERFORMANCE |
| | RESIST | RESIST |
| NA | PROCESS (μm) | PROCESS (μm) |
| 0.9 | 0.10 | 0.14 |
| 0.85 | 0.10 | 0.15 |
| 0.8 | 0.11 | 0.16 |
| 0.79 | 0.11 | 0.16 |
| 0.78 | 0.11 | 0.16 |
| 0.77 | 0.11 | 0.16 |
| 0.76 | 0.11 | 0.16 |
| 0.75 | 0.12 | 0.17 |
| 0.74 | 0.12 | 0.17 |
| 0.73 | 0.12 | 0.17 |
| 0.72 | 0.12 | 0.17 |
| 0.71 | 0.12 | 0.17 |
| 0.7 | 0.12 | 0.18 |
| 0.69 | 0.13 | 0.18 |
| 0.68 | 0.13 | 0.18 |
| 0.67 | 0.13 | 0.19 |
| 0.66 | 0.13 | 0.19 |
| 0.65 | 0.13 | 0.19 |
| 0.64 | 0.14 | 0.19 |
| 0.63 | 0.14 | 0.20 |
| 0.82 | 0.14 | 0.20 |
| 0.61 | 0.14 | 0.20 |
| 0.6 | 0.14 | 0.21 |

The dimensions obtained by the foregoing optical calculation are values standardized by the exposure light wavelength λ and the numerical apertures NA of the projection lenses that are respective simulation parameters.

Referring to FIG. 5B, a chevron pattern obtained by using this invention is defined in shape based on a mathematical interpretation wherein, in a resist pattern having a resist portion 149 and an aperture portion 148, a wavy shape is taken as its pseudo-amplitude values. Herein, an index called a degree of chevron (hereinafter referred to as “DC”) is provided and defined as DC=(large-aperture length 146)/(constriction minimum width 147). Therefore, when the width 145 in FIG. 5A changes, a region where a calculated degree of chevron is 1<DC<∞, i.e. where constriction minimum width 147<large-aperture length 146 and constriction minimum width 147≠0, is considered to be “desired chevron shape” and the width (mask pattern pitch) 145, shown in FIG. 5A, in this range is prescribed to fall within the process allowable range that can achieve the technical effect by this invention.

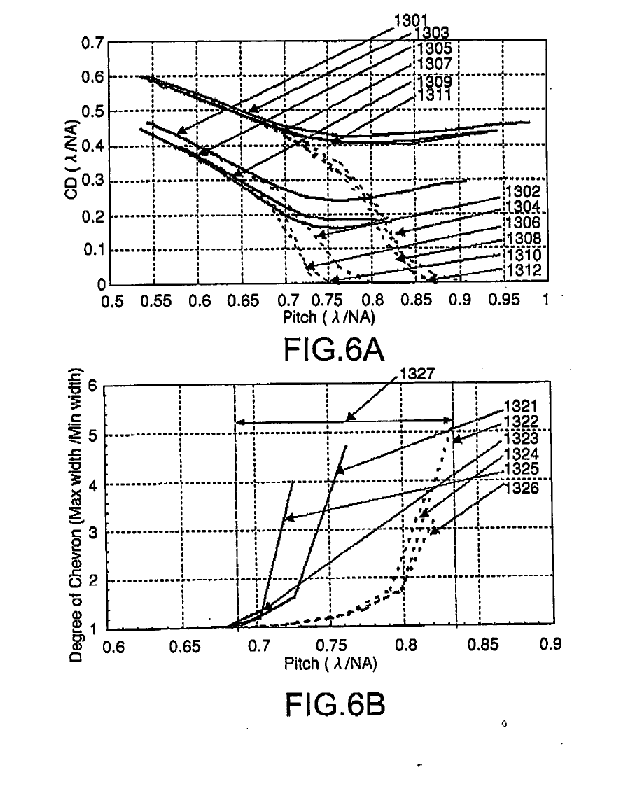

FIG. 6A shows dependence properties of the large-aperture length 146 in FIG. 5B and the constriction minimum width 147 in FIG. 5B relative to the mask pattern pitch 145 in FIG. 5A. In FIG. 6A, data specified by 1301 and 1302, 1303 and 1304, 1305 and 1306, 1307 and 1308, 1309 and 1310, and 1311 and 1312 show dimensional properties respectively calculated under various process conditions in which the projection lens numerical aperture NA and the resist resolution performance are mutually different. Herein, under the same process condition, values corresponding to the aperture length 146 in FIG. 5B correspond to 1301 while values corresponding to the aperture width 147 in FIG. 5B correspond to 1302, which also applies to 1303 and 1304, 1305 and 1306, 1307 and 1308, 1309 and 1310, and 1311 and 1312, respectively. Degrees of chevron calculated by DC=(aperture length 146 in FIG. 5B)/(aperture width 147 in FIG. 5B) for the respective process conditions are plotted against the mask pattern pitches 145 in FIG. 5A based on FIG. 6A to thereby obtain FIG. 6B.

Respective data items shown in FIG. 6B are such that 1321 represents the degrees of chevron corresponding to the high NA/high resolution resist process, 1322 corresponding to the high NA/low resolution resist process, 1323 corresponding to the intermediate NA/high resolution resist process, 1324 corresponding to the intermediate NA/low resolution resist process, 1325 corresponding to the low NA/high resolution resist process, and 1326 corresponding to the low NA/low resolution resist process. By gradually increasing the pattern pitch, DC=1 at a critical point where the shape of the transferred pattern starts to be wavy, 1<CD in a region where DC=1 is exceeded and the dimensional difference is caused with periodicity in the transferred pattern, and the aperture width 147 in FIG. 5B becomes zero with the pattern pitch where the minimum-width line is disconnected, so that DC=∞. On the graph, calculation is made of a critical point of the pattern pitch where disconnection occurs with an accuracy of 0.01λ/NA, and limited property data up to the critical point are plotted. Therefore, a set region 1327 (FIG. 6B) obtained by calculating per process condition a width of the pattern pitch where the degree of chevron DC satisfies 1<DC<∞ and deriving the logical sum of the calculated widths with respect to all process conditions, represents an allowable standard range of the pattern pitch where a desired chevron shape is obtained regardless of the process condition, and the prescription range becomes 0.69/λNA≦pattern pitch≦0.85λ/NA.

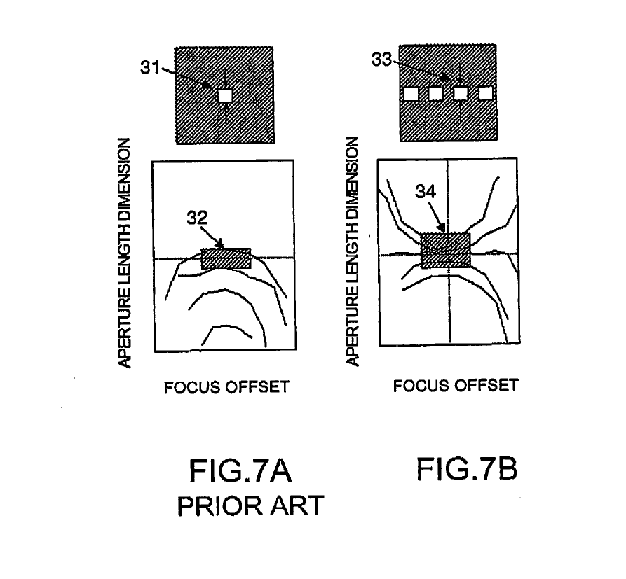

Referring to FIGS. 7A and 7B, description will be given about behavior of the resist dimensional property upon occurrence of a focus change. FIG. 7A shows a CD-focus property of a discrete hole, while FIG. 7B shows a CD-focus property of a resist pattern having a chevron shape.

Forming an aperture in a chevron shape provides a large merit also in terms of processing. As shown in FIG. 7A, let a mask pattern 31 be formed as a conventional simple hole pattern. In this case, a characteristic curve obtained by plotting aperture length dimensions that vary following a change in focus offset value forms a shape that is quite convex upward. This represents that the rate of the dimensional change of the aperture portion relative to the focus offset change is extremely large. A process variation range that can satisfy a dimensional standard of a target dimension±A % (A is an upper limit/lower limit value of an allowable range) was calculated from dimensional variation amounts that are allowable within a range not impeding the device operation, and defined as a process tolerance. Therefore, the process tolerance of the discrete hole calculated from the characteristic curve in FIG. 7A becomes a range of a rectangular region 32.

On the other hand, as shown in FIG. 7B, in case of a mask pattern 33 having a chevron shape, the focus dependence property of the dimension is broadly expanded relative to focus offset variation values on an X-axis so that an effective process region 34 largely increases as compared with the effective process region 32 in FIG. 7A. This means that it is reluctant to depend on a change in process condition that occurs in the semiconductor manufacture, thereby making it easy to keep high quality of the devices.

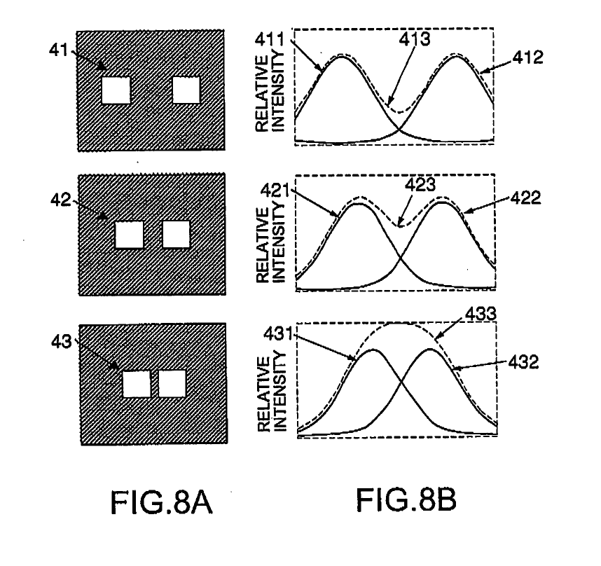

Referring to FIGS. 8A and 8B, description will be given about a correlation between a mask pattern shape and a light intensity distribution. FIG. 8A shows mask pattern images, while FIG. 8B shows light intensity distributions. By reducing the separation width between aperture portions on a mask from a mask pattern 41 to a mask pattern 42 and further to a mask pattern 43 as shown in FIG. 8A, the maximum peak intensities, at both aperture portions, of optical waveforms 421 and 422 in the light intensity distribution shown in FIG. 8B increase like an optical waveform 423 due to a mutual optical image adding effect where optical images between both aperture patterns interfere with each other. On the other hand, if the separation width is reduced to that of the mask pattern 43, an optical waveform in the sum of optical waveforms 431 and 432 becomes a single waveform like an optical waveform 433 so that a chevron shape is not formed. Therefore, it is suggested that the pattern pitch of 0.69λ/NA≦pattern pitch≦0.85λ/NA be satisfied as the mask pattern 42 also in terms of the light intensity.

This invention is a semiconductor device manufacturing method that is quite effective for forming a resist mask pattern for ion implantation requiring a critical processing dimensional accuracy and a specific shape, in a DRAM device that requires formation of a high-density superfine circuit pattern among semiconductor integrated circuits.

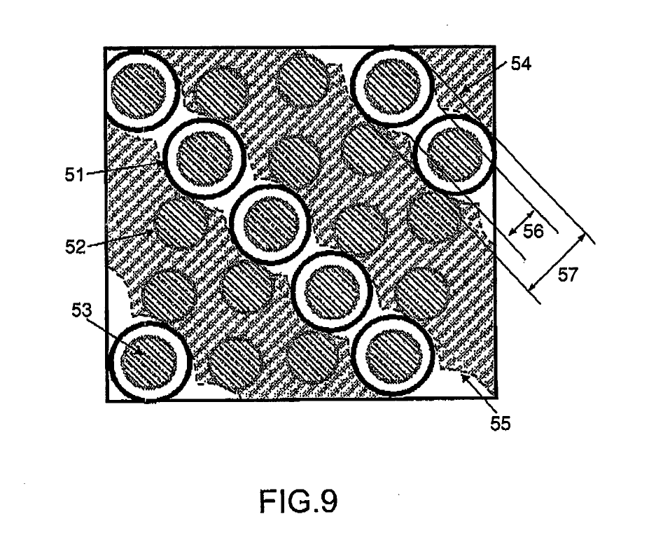

Referring to FIG. 9, description will be given about an example of application to an ion-implantation resist mask process requiring a chevron shape. The ion-implantation resist mask pattern forming process is such that, in an 8F² cell ¼ pitch DRAM memory cell, a resist is applied and formed over plug holes 52 and 53 having already been formed, apertures are selectively formed in the resist only at portions corresponding to the plug holes 53 in terms of circuit function, and ion implantation is carried out only into the plug holes 53 using the resist as a shielding mask. A desired resist shape becomes a pattern 55 in which regions 51 requiring apertures and regions connecting between the adjacent regions 51 in a manner to avoid the plug holes 52 are formed into a continuous aperture. Therefore, since the resist pattern has side walls having a wavy shape with respect to its continuing direction, it is called a pattern having a chevron feature.

When forming the desired resist pattern 65, let an optical image be formed on a resist by the use of the first or second conventional technique 11 or 12 having the mask layout equivalent to the desired resist shape as shown in FIG. 3A. In this case, a difference in light intensities at the adjacent large-aperture portion A4 and constricted portion A5 becomes very small, in other words, optical images of both patterns become equivalent on the same light intensity level. Therefore, an optical image actually transferred onto the resist becomes the rectangular pattern A1 that is continuous in a straight bar shape. Accordingly, not only the plug holes 53 in FIG. 9 but also the plug holes 52 in FIG. 9 are subjected to the formation of aperture so that it does not function as an ion-implantation shielding mask.

On the other hand, let the third conventional technique 13 having serifs as OPCs for transferring the shapes of the corners or the bent portions with emphasis or the fourth conventional technique 14 having inverted serifs as such OPCs, as shown in FIG. 3A, be applied to the mask pattern having the rectangular shape. In this case, FIG. 3A is taken as the pattern shown in FIG. 3B wherein the large-area rectangular patterns A6 and the node patterns A7 each arranged therebetween are connected together. Then, the length of each large-area rectangular pattern A6 in FIG. 3B is resized to be greater as compared with the corresponding portion in FIG. 3A while the width of each node pattern A7 in FIG. 3B is resized to be smaller as compared with the corresponding portion in FIG. 3A, independently of each other. This is for increasing the light intensity at each large-area rectangular pattern A6 in FIG. 3B while reducing the light intensity at each node pattern A7 in FIG. 3B, thereby obtaining a chevron-like wavy transferred shape by utilizing a phenomenon that the resist aperture width becomes thicker at the high light intensity portion while thinner at the low light intensity portion.

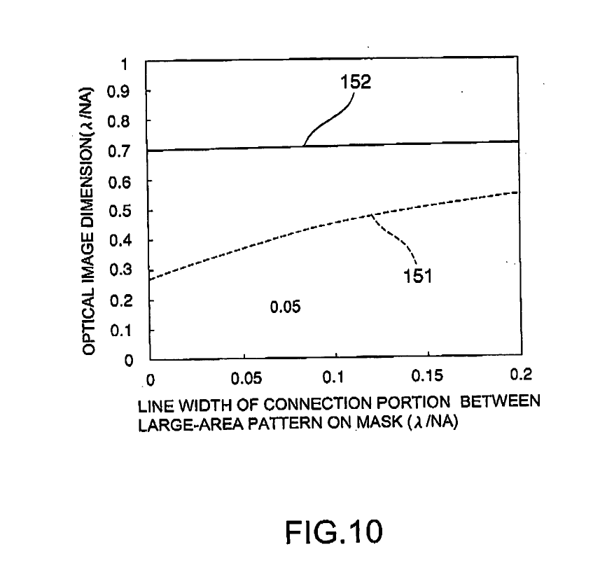

FIG. 10 shows dependency of an optical image dimension relative to a width of the node portion. FIG. 10 is obtained by calculating, in an optical image of the node pattern A7 in FIG. 3B, optical image dimensions at a portion where the optical contrast is most reduced at the center of the node pattern A7, in cases where the width of the node pattern A7 on a mask is decreased in order from 0.22λ/NA (fifth conventional technique 15) to 0.15λ/NA (sixth conventional technique 16) and further to 0.07λ/NA (seventh conventional technique 17) shown in FIG. 3B, and then plotting them as optical image dimensions at the center of the node pattern A7 relative to the width thereof.

In FIG. 10, numeral 151 denotes an optical image dimension variation at the center of the node pattern A7 in FIG. 3B, while numeral 152 denotes an optical image dimension of the large-area rectangular pattern A6 in FIG. 3B. The image dimension 152 is substantially constant regardless of the line width of the node pattern A7 on the mask. On the other hand, with respect to the image dimension variation 151, as the line width of the node pattern A7 decreases, the image dimension thereof enables resolution of a finer dimension region and, when the line width of the node pattern A7 is zero, the image dimension thereof enables formation of the finest dimension.

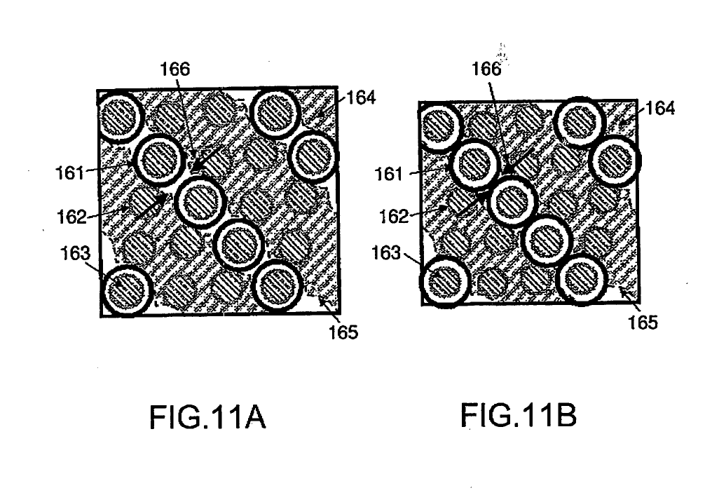

FIG. 11A shows a pattern image based on the current layout rule, while FIG. 11B shows a pattern image when the pattern image in FIG. 11A is shrunk to 90%.

The minimum aperture width of a chevron pattern allowed by the design rule in FIG. 11A corresponds to a width 166 in FIG. 11A. On the other hand, if the resolution ability of each region 161 requiring an aperture in FIG. 11B remains the same as that of a current region 161 requiring an aperture in FIG. 11A in the layout where the design rule is shrunk to 90% as shown in FIG. 11B, an aperture width 166 of each constricted portion in FIG. 11B should be set very small for opening plug holes 163 in FIG. 11B without opening plug holes 162 in FIG. 11B. This requires extremely high processing controllability to be essential. Therefore, in order to form a desired chevron pattern with high controllability, the new technique 18 is most desirable wherein the line width of the node pattern A7 in FIG. 3B is set to zero, i.e. the large-area rectangular patterns A6 in FIG. 3B are separated from each other. Further, in the mask layout according to the new technique 18 in FIG. 3C, the dimension of the constricted portion A3 of the resist aperture portion in FIG. 3C can be easily controlled by optimizing the pitch between the large-area mask patterns A8 in FIG. 3C within the prescribed range.

Now, description will be given about a case where the semiconductor device manufacturing method according to this invention is applied to an asymmetric implantation resist mask forming process of an 8F² cell ¼ pitch DRAM device with a design rule of 0.13 μm.

Referring to FIG. 9, it is necessary that a desired ion-implantation shielding resist mask have the chevron shape identified by the aperture region 55. Taking into account misalignment with underlying plugs and dimensional variation caused by instability of the process and in a range with no impedance in terms of processing, a necessary and sufficient allowable dimension range is prescribed such that an aperture width 57 is set to 0.36 to 0.4 μm and an aperture width 56 is set to 0.2 μm or less. Therefore, a mask layout pattern that can match this process should satisfy 0.69λ/NA≦P≦0.85λ/NA (P: pattern pitch) and DC≧0.36/0.2=1.8 (DC: degree of chevron).

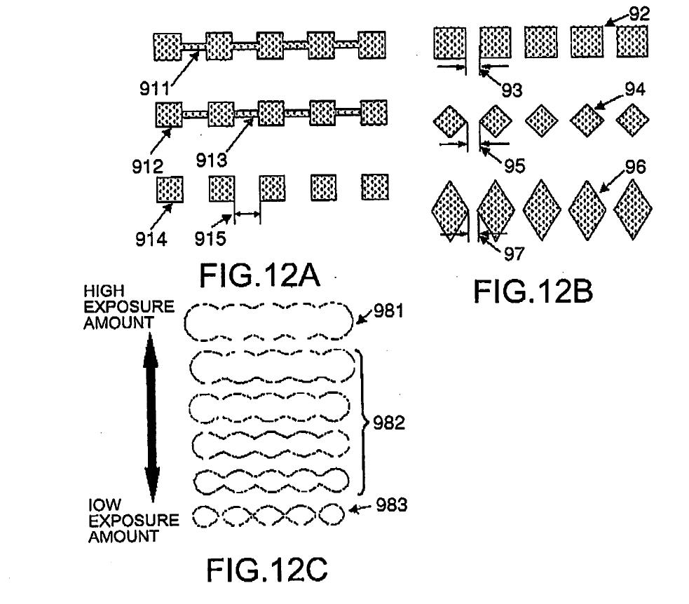

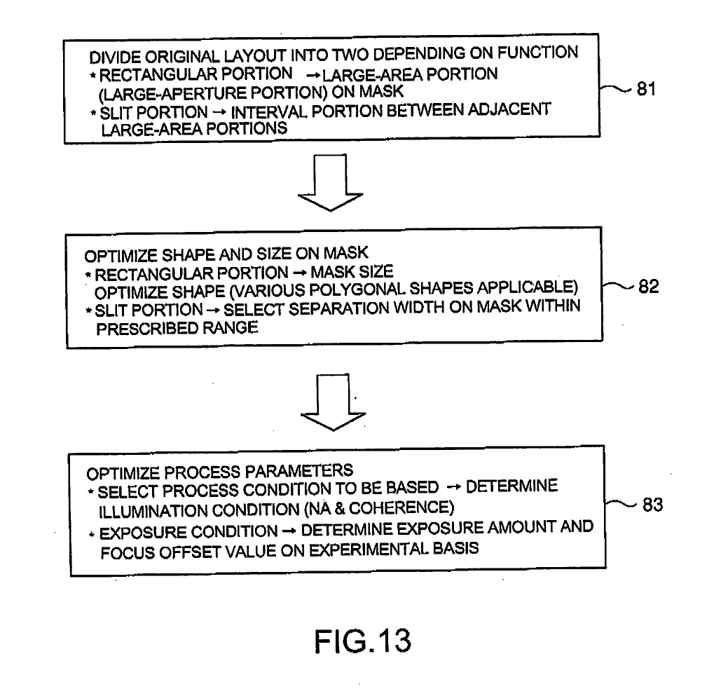

Referring to FIGS. 12A, 12B, and 12C in addition to FIG. 13, the operation procedure of this invention will be described. FIG. 13 is a flowchart showing the operation procedure of this invention. FIGS. 12A, 12B, and 12C are detailed explanatory diagrams for the operation procedure of this invention, wherein FIG. 12A shows pattern extraction from an original layout, FIG. 12B shows optimization of a mask pattern size, and FIG. 12C shows optimization of the process condition.

In step 81 in FIG. 13, a mask layout 911 equivalent to a desired resist shape is assumed as an original layout as shown in FIG. 12A. Then, it is assumed that the original layout 911 has a shape formed by large-aperture rectangular portions 912 and connection portions 913 therebetween that are connected together. Then, by removing only the connection portions 913 to thereby form slits 915, the original layout 911 is simplified as a pattern in which square aperture patterns 914 are arranged with the separation width 915 defined between the adjacent aperture patterns 914.

Subsequently, in step 82 in FIG. 13, rectangular portions 92 in FIG. 12B are formed by changing the size of each square aperture pattern 914 in FIG. 12A, and slit portions (separation width) 93 in FIG. 12B are formed by optimizing the separation width 916 in FIG. 12A based on the prescribed pitch range. Herein, depending on a final resist shape, and a final aperture area and aperture shape of a large-aperture portion, the shape and size of the rectangular portion 92 in FIG. 12B may be changed to those of a rectangular portion 94 in FIG. 12B or a rectangular portion 96 in FIG. 12B. In this event, it is also necessary to simultaneously optimize a separation width 95 or 97 as shown in FIG. 12B. The mask shape 92, 94, or 96 to be adopted differs depending on the optical condition of a lighting to be used, the resolution performance of a resist material to be used, and further the degree of chevron of a desired pattern. In case of using a transfer process having a high resolution performance, it is desirable to adopt the mask shape 92, because of its high transfer fidelity, in which the shape of the large-aperture portion is substantially equivalent to that of the original pattern. On the other hand, when the resolution performance is low, since the optical contrast at the large-aperture portion decreases, it is necessary to increase the area of the large-aperture portion on the mask to compensate for shrinkage upon transfer. In view of this, it is effective to use the mask shape 94 shown in FIG. 12B which increases the dimensional controllability at the separation portion by rotating the mask shape 92 in FIG. 12B by 45 degrees, or the mask shape 96 shown in FIG. 12B which enlarges the mask pattern in a direction where shrinkage is liable to occur (a direction perpendicular to a direction where the pattern continues).

Finally, in step 83 in FIG. 13, a photomask with the optimized mask layout formed thereon is produced and pattern transfer is actually carried out. Herein, as shown in FIG. 12C, after adjusting a focus offset value based on the optimized illumination optical condition, conditions 982 that can achieve the desired resist dimensions are determined by changing the exposure amount. Herein, assuming a case where the stability of the exposure tool or the condition of the wafer substrate may change, the determined conditions should ensure the least change in resist dimension that occurs in response to the change in focus offset value or exposure amount. In view of this, it can be said that each of conditions 981 and 983 is not suitable because the resist shape and size largely change following the change in focus offset value or exposure amount.

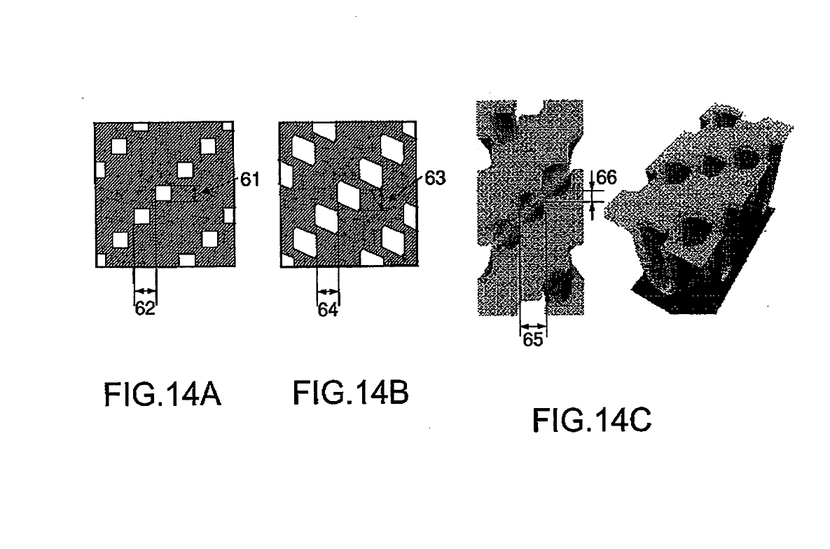

Referring now to FIGS. 14A, 14B, and 14C, description will be given about a mask pattern and a resist shape image. FIG. 14A shows a first mask layout pattern, FIG. 14B shows a second mask layout pattern, and FIG. 14C is an image diagram of a resist profile.

This time, when optimizing the asymmetric implantation mask layout pattern, pattern dimensions and pitches were used as parameters and combined with each other, in all possible combinations, to carry out optical simulation under the respective combined conditions in the high resolution process and the current process, respectively. When dimensions of an obtained optical image could achieve dimensions and a shape necessary for a device, corresponding mask dimensions were determined to be optimum.

Herein, the present inventors have concluded that a square pattern with a pattern aperture length 61 of 0.198 μm and a pattern pitch 62 of 0.27 μm as identified by the first mask layout pattern in FIG. 14A is adequate in the high NA exposure process (exposure light wavelength λ: 0.248 μm, KrF excimer laser, numerical aperture NA of a projection lens: 0.8, high resolution positive tone resist process). Further, the present inventors have concluded that a rhombic pattern with a pattern aperture length 63 of 0.27 μm and a pattern pitch 64 of 0.27 μm as identified by the second mask layout pattern in FIG. 14B is adequate in the intermediate/low NA exposure process (exposure light wavelength λ: 0.248 μm, KrF excimer laser, numerical aperture NA of a projection lens: 0.68, positive tone resist process with satisfactory results). Upon application to the actual products, the second mask layout in FIG. 14B has been adopted because it can use the existent facilities and the resist process that have satisfactory results.

FIG. 14C shows a profile of a resist pattern obtained by the use of a photomask produced according to this invention. A quite excellent chevron shape was obtained having resist dimensions with an aperture length 65 of 0.36 μm, minimum line width 66 of 0.1 μm, and a degree of chevron of 3.0. This invention is also applicable to formation of a transfer path pattern of a magnetic bubble memory.

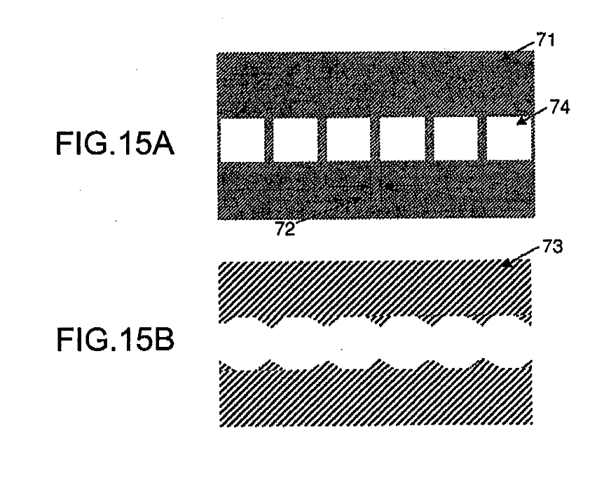

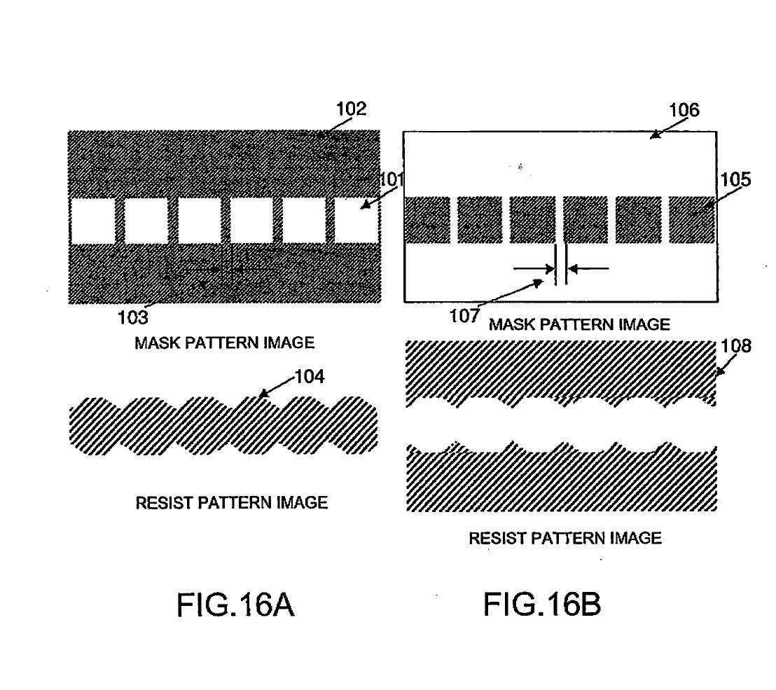

Now, referring to FIGS. 15A and 15B in addition to FIGS. 16A and 16B, description will be given about another embodiment of this invention. FIG. 16A shows formation of a line chevron pattern, while FIG. 16B shows a shape of an aperture pattern having a chevron shape by the use of a negative tone resist. FIGS. 15A and 15B are diagrams showing an outline of a resist pattern forming process having a chevron shape, wherein FIG. 15A shows a mask layout pattern while FIG. 15B is a resist pattern image diagram.

Assuming the formation of a continuous aperture pattern having a chevron shape, in the foregoing embodiment, the mask layout, as shown in FIG. 16A, has aperture portions 101 formed as transmitting layers (glass portions) and the other portion formed as a shielding layer 102, with gaps 103 each having a prescribed dimension and each defined between the adjacent transmitting layers 101 for separation thereof. The positive tone resist process is generally used with this mask layout and, based on the combination thereof, a desired aperture pattern 73 is obtained as shown in FIG. 15B. In view of this, in another embodiment of this invention, it is possible to form a line resist pattern 104 with a desired chevron shape as shown in FIG. 16A by the use of the same mask layout and a negative tone resist process.

On the other hand, a resist aperture pattern 108 with a chevron shape as shown in FIG. 16B can be obtained by inverting white and black of the transmitting layers 101 and the shielding layer 102 in FIG. 16A to produce a mask with shielding layers 105 and a transmitting layer 106 as shown in FIG. 16B and further by using a negative tone resist. In terms of the shape, the resist aperture pattern 108 in FIG. 16B is equivalent to the aperture pattern 73 shown in FIG. 15B. However, since the resist portion is the negative tone resist, there is an advantageous point in terms of processing. In the negative tone resist, exposed portions are bridged by photochemical reaction to exhibit nonsolubility in a later development process so that the resist remains only at the exposed portions. During this process, the molecular weight of macromolecules forming the resist rises to increase a hardness of the resist itself. Therefore, even in case of a resist pattern with the same shape, there are those instances where it is better to use a negative tone resist rather than a positive tone resist having generally been used depending on a use of a photomask during the processing. This time, in order to increase the ion shielding effect as the ion-implantation resist mask, it is effective to use the process in FIG. 16B using the negative tone resist process.

1. A semiconductor device manufacturing method for forming on a resist a chevron pattern having continuity and periodically having aperture portions, said method comprising the steps of:
forming a photomask having a mask layout pattern with separated aperture patterns arranged at a pattern pitch P prescribed by 0.69λ/NA≦P≦0.85λ/NA where λ is an exposure light wavelength and NA is the numerical aperture of a projection lens; and
transferring said mask layout pattern onto said resist to form a desired chevron shape by processingly connecting optical images of said aperture patterns.

2. A semiconductor device manufacturing method according to claim 1, wherein a slit pattern having said chevron shape is formed by transferring said mask layout pattern onto a positive tone resist as said resist.

3. A semiconductor device manufacturing method according to claim 1, wherein a line pattern having said chevron shape is formed by transferring said mask layout pattern onto a negative tone resist as said resist.

4. A semiconductor device manufacturing method according to claim 1, wherein each of said aperture portions has a rectangular shape.

5. A semiconductor device manufacturing method according to claim 1, wherein each of said aperture portions has a rhombic shape.

6. A semiconductor device manufacturing apparatus for forming on a resist a chevron pattern having continuity and periodically having aperture portions,
wherein a photomask for transferring the chevron pattern onto said resist has a mask layout pattern with separated aperture patterns arranged at a pattern pitch P prescribed by 0.69λ/NA≦P≦0.85λ/NA where λ is an exposure light wavelength and NA is the numerical aperture of a projection lens.

7. A semiconductor device manufacturing apparatus according to claim 6, wherein said resist is a positive tone resist.

8. A semiconductor device manufacturing apparatus according to claim 6, wherein said resist is a negative tone resist.

9. A semiconductor device manufacturing apparatus according to claim 6, wherein each of said aperture portions has a rectangular shape.

10. A semiconductor device manufacturing apparatus according to claim 6, wherein each of said aperture portions has a rhombic shape.

11. A photomask for transferring onto a resist a chevron pattern having continuity and periodically having aperture portions,
wherein said photomask has a mask layout pattern with separated aperture patterns arranged at a pattern pitch P prescribed by 0.69λ/NA≦P≦0.85λ/NA where λ is an exposure light wavelength and NA is the numerical aperture of a projection lens.
